(19) United States
(12) Patent Application Publication
(10) Pub. No.: US 2012/0252174 A1
(43) Pub. Date: Oct. 4, 2012

(54) PROCESS FOR FORMING AN EPITAXIAL LAYER, IN PARTICULAR ON THE SOURCE AND DRAIN REGIONS OF FULLY-DEPLETED TRANSISTORS

(75) Inventors: Didier Dutartre, Meylan (FR); Nicolas Loubet, Guilderland, NY (US); Yves Campidelli, Le Moutaret (FR); Denis Pellissier-Tanon, Grenoble (FR)

(73) Assignees: STMicroelectronics (Crolles 2) SAS, Crolles Cedex (FR); STMicroelectronics S.A., Montrouge (FR)

(21) Appl. No.: 13/434,923

(22) Filed: Mar. 30, 2012

(30) Foreign Application Priority Data
Apr. 1, 2011 (FR) 1152821

(51) Int. Cl. H01L 21/336; H01L 21/20

(52) U.S. Cl. 438/151; 438/481; 257/E21.09; 257/E21.415

(57) ABSTRACT

A layer of a semiconductor material is epitaxially grown on a single-crystal semiconductor structure and on a polycrystalline semiconductor structure. The epitaxial layer is then etched in order to preserve a non-zero thickness of said material on the single-crystal structure and a zero thickness on the polycrystalline structure. The process of growth and etch is repeated, with the same material or with a different material in each repetition, until a stack of epitaxial layers on said single-crystal structure has reached a desired thickness. The single crystal structure is preferably a source/drain region of a transistor, and the polycrystalline structure is preferably a gate of that transistor.

### PRIORITY CLAIM

This application claims priority from French Application for Patent No. 1152821 filed Apr. 1, 2011, the disclosure of which is incorporated by reference.

### TECHNICAL FIELD

The invention relates to microelectronics, and especially to the formation of epitaxial layers of semiconductor material, in particular epitaxial layers forming source or drain regions of transistors such as fully-depleted transistors produced on silicon-on-insulator (SOI) substrates.

### BACKGROUND

Epitaxial growth steps can be used to control the electrical properties of the source and drain regions of insulated-gate transistors. It is possible in particular to control the dopant levels present within these single-crystal regions by introducing dopants into the epitaxial silicon layers. It is also possible to introduce germanium or carbon atoms in order to modify the mechanical strain in the epitaxial layers and increase the mobility of charge carriers in the source and drain regions.

Furthermore, the gates of transistors conventionally comprise at least one polycrystalline silicon layer, possibly deposited on a metal layer.

If the source and drain regions are formed by epitaxy, an epitaxial layer may also appear on the polysilicon-comprising gates of the transistors. Epitaxial growth on the gate is furthermore promoted by the polycrystalline structure, which comprises single-crystal silicon grains and boundaries between these grains similar to an amorphous material. A mushroom-shaped protuberance may then be formed on the gate, the thickness of which may be greater than the thickness grown epitaxially on the source and drain regions.

If the transistors are produced in advanced technologies, for example with gate lengths smaller than 32 nanometers, the presence of this epitaxially grown protuberance on the gates of the transistors may cause short-circuits between neighboring gates, or else between the source/drain contact pads and the transistor gates.

Moreover, fabrication of integrated circuits comprising fully-depleted transistors on a silicon-on-insulator (SOI) substrate may comprise epitaxial growth of semiconductor material, said epitaxial growth being intended to thicken the source and drain regions. This thickening may in particular make it easier to form a metal silicide on said regions with a view to creating a contact pad. The source and drain regions of a fully-depleted transistor have, before this epitaxial growth, a thickness of about two or three nanometers. In order to obtain a silicon thickness allowing contacts to be formed, epitaxial growth of about twenty nanometers of material may be carried out. Such epitaxial growth may therefore cause a thick epitaxial protuberance to appear on the gates of the fully-depleted transistors, with the aforementioned drawbacks.

It has been proposed to use a hard mask on the gate of the transistor so as to prevent the silicon protuberance from forming. This being so, use of a hard mask is costly and complicated to implement.

### SUMMARY

According to one implementation, it is proposed to improve epitaxial growth of semiconductor material so as to obtain a desired thickness of epitaxial material on a single-crystal structure and a zero thickness on a polycrystalline structure.

According to one aspect, a process is proposed that comprises: (a) growing a layer of a semiconductor material epitaxially on a single-crystal semiconductor structure and on a polycrystalline semiconductor structure; (b) etching said epitaxial layer in order to preserve a non-zero thickness of said material on the single-crystal structure and a zero thickness on the polycrystalline structure; and (c) repeating step (a) at least once, with the same material or with a different material, said single-crystal structure and said polycrystalline structure being obtained, respectively, from the preceding step (b), and repeating step (b) at least once, until the stack of epitaxial layers on said single-crystal structure has reached the desired thickness.

The rate of the epitaxial growth steps and the rate of the etch steps depend on the structure of the material to be etched. More precisely, epitaxial growth is faster on a polycrystalline material than on a single-crystal material, and a possibly epitaxial polycrystalline material etches faster than a single-crystal material.

By way of example, if a silicon layer is epitaxially grown on single-crystal silicon, for example a drain or source of a transistor, and on polysilicon, for example a gate of a transistor, it is possible to obtain growth rates of about five nanometers per minute on the single-crystal structure and of about 10 nanometers per minute on the polycrystalline structure. In an etching step, it is possible to obtain an etch rate of about 1 nanometer per minute on the single-crystal structure, and about 10 nanometers per minute on the polycrystalline structure.

Thus, by repeating epitaxial growth and etching on single-crystal and polycrystalline structures, it is possible to obtain a controlled thickness of epitaxial material on the single-crystal structure and a zero thickness on the polycrystalline structure.

Advantageously, the process furthermore comprises initial epitaxial growth of an initial semiconductor material on an initial single-crystal structure and an initial polycrystalline structure, for example initially thin source/drain regions within an SOI substrate and gate regions for fully-depleted transistors, so as to obtain said single-crystal structure and said polycrystalline structure on which the one or more epitaxial growth/etching loops will be carried out, said initial epitaxial growth being carried out at a temperature below that of the epitaxial growth of step (a).

The initial epitaxial growth in particular solidifies and prepares the surface of the single-crystal structure.

Implementing this initial epitaxial growth at a temperature below that of the epitaxial growth of step (a) is particularly applicable to the thinnest silicon layers, for example the drains and sources of a fully-depleted transistor.

It is also possible to implement the initial epitaxial growth during temperature ramp and stabilization phases, and possibly as soon as the materials have been loaded into an epitaxial reactor.

These thin layers, for example having a thickness smaller than ten nanometers, are unstable at high temperatures.

Initial epitaxial growth at a temperature at which these thin single-crystal structures will remain stable makes it possible to obtain a small thickness increase that may be sufficient to provide the single-crystal structures with the stability required for steps (a) and (b).

Moreover, steps (a) and (b) are implemented at higher temperatures so as to obtain higher rates.

The thin layers may be damaged by possible prior etch steps. Thus, the single-crystal layers may be partially amorphous if the crystalline structure has been damaged.

The temperature at which the initial epitaxial growth is carried out may allow the single-crystal structures to recrystallize.

A person skilled in the art will know how to choose the temperatures of the initial epitaxial growth in order not to damage the single-crystal structure, so as to allow the single-crystal structure to be solidified, and in order to enable recrystallization.

Advantageously, the process furthermore comprises, after the initial epitaxial growth, an initial etch in order to preserve a non-zero thickness of said material on the initial single-crystal structure and a zero thickness on the initial polycrystalline structure, said initial etch being carried out at a temperature below that of the etch of step (b).

The process may comprise a final step of growing a semiconductor material epitaxially on the single-crystal structure and polycrystalline structure obtained after the last step (b).

In this way the surface finish of the epitaxial material is obtained.

Advantageously, steps (a) and (b) are carried out in one and the same epitaxial reactor at a constant temperature.

Steps (a) and (b) may also be carried out in one and the same epitaxial reactor at a constant pressure.

Using one and the same reactor at a constant pressure and/or a constant temperature makes it possible to simplify control of the epitaxial growth and etching steps.

Using one and the same reactor also allows the productivity of the process to be increased.

Furthermore, control of the etch and epitaxial growth rates is simplified.

### BRIEF DESCRIPTION OF THE DRAWINGS

Other advantages and features of the invention will become clear on studying the detailed description of non-limiting methods of implementation, given by way of example, and illustrated by the annexed drawings in which:

FIGS. 1, 2 and 3 illustrate a method of implementation according to the invention.

### DETAILED DESCRIPTION OF THE DRAWINGS

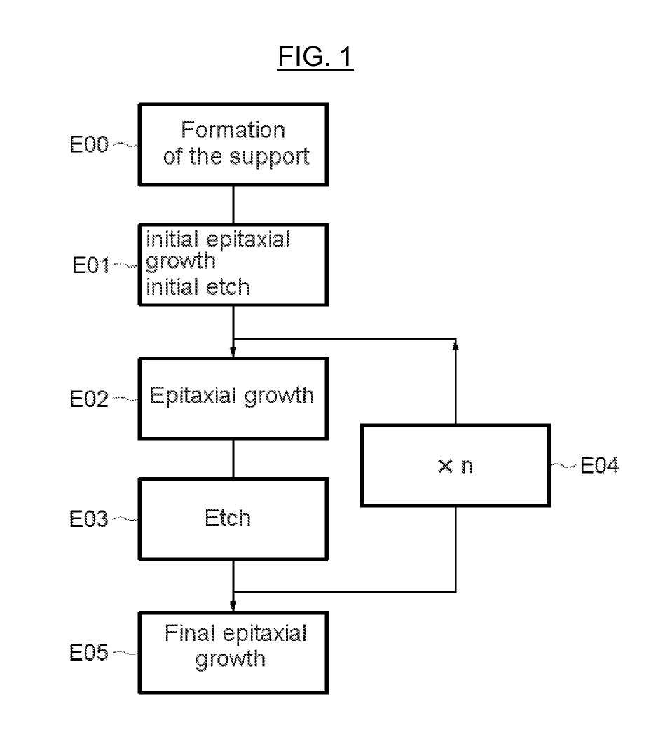

FIG. 1 describes schematically the steps of a process according to one aspect.

In a first step E00 a support is formed on which it is desired to form an epitaxial layer. This step E00 possibly comprises forming a semiconductor substrate or a silicon-on-insulator (SOI) substrate, and forming at least an initial single-crystal structure and an initial polycrystalline structure. The single-crystal structure may be contained in the support, for example in the SOI substrate. The polycrystalline structure may be an insulated gate region produced on the substrate, on part of the initial single-crystal structure.

Of course, the formation of the support may comprise forming other components in semiconductor materials other than silicon.

A step E01 of initial epitaxial growth of an initial material and of initial etching is then optionally carried out.

Step E01 is in particular applicable to the thinnest structures, for example less than ten nanometers in thickness, because this step allows the initial single-crystal structure to be solidified, and it also allows this structure to be recrystallized.

By way of example, it is possible, in this initial step, to grow a layer of silicon epitaxially at a temperature of about 600° C., using a gas mixture comprising dichlorosilane (SiH₂Cl₂) and hydrochloric acid (HCl).

This step E01 also comprises an initial etch, so as to leave a non-zero thickness of said initial epitaxially grown material on the initial single-crystal structure and a zero thickness on the initial polycrystalline structure.

This initial etch may comprise chemical etching by means of gaseous hydrochloric acid (HCl). The etch rate is furthermore controlled so as to leave a non-zero thickness of said initial material on the initial single-crystal structure.

The temperature of this initial step E01 may be chosen so as to preserve the stability of the initial single-crystal structure while allowing this structure to be recrystallized.

By way of example, for epitaxial growth of silicon, a temperature of about 600° C. may be used, and for epitaxial growth of a silicon-germanium alloy comprising at least 30% germanium, a temperature of about 550° C. may be used.

Moreover, the duration of the initial steps of epitaxial growth and etching may for example be about one minute.

Step E01 therefore allows a stable and robust single-crystal structure to be obtained, capable of retaining its properties at higher temperatures.

The initial polycrystalline structure is not modified by step E01 and forms a polycrystalline structure.

It is to these single-crystal and polycrystalline structures that epitaxial growth and etching cycles will now be applied.

More precisely, epitaxial growth E02 of a layer of a semiconductor material is then carried out on the single-crystal structure and on the polycrystalline structure.

This step is carried out at a higher temperature than the temperature of step E01. It is thus possible to obtain a sufficiently high growth rate. It is possible for example to form a silicon layer, at a temperature of about 700° C. to 750° C., using a gas mixture comprising dichlorosilane (SiH₂Cl₂) and hydrochloric acid (HCl).

For epitaxial growth of a layer of a silicon-germanium alloy, a temperature of about 600° C. to 650° C. will for example be used. The semiconductor material to be grown epitaxially may also be chosen from the group consisting of silicon, germanium, a silicon-germanium alloy, a silicon-carbon alloy and a silicon-germanium-carbon alloy.

A person skilled in the art will be able to adjust the temperatures of this step E02, depending on the material layers to be formed, and the duration of this step, for example about a minute, depending on the thickness to be grown epitaxially.

By way of example, step E02 may be carried out at a pressure of about 20 torr, with a gas mixture containing for example dichlorosilane (SiH₂Cl₂) at a partial pressure of 50 millitorr and hydrochloric acid (HCl) at a partial pressure of 30 millitorr.

The layer of semiconductor material grown epitaxially on the single-crystal structure is thinner than the layer of material grown epitaxially on the polycrystalline structure.

This is because epitaxial growth is promoted by the polycrystalline structure, which comprises grains having grain boundaries that are almost amorphous.

By way of example, it is possible to obtain a layer growth rate of about five nanometers per minute on the single-crystal structure compared to ten nanometers per minute on the polycrystalline structure.

An etching step is then carried out (step E03).

This step comprises chemical etching by means of a gas comprising for example hydrochloric acid (HCl).

Since the polycrystalline structure etches faster than the single-crystal structure, this step allows a non-zero thickness of semiconductor material to be preserved on the single-crystal structure, and zero thickness of the material to be formed on the polycrystalline structure.

By way of example, it is possible to obtain an etch rate for the layer of about 1 nanometer per minute on the single-crystal structure compared to 10 nanometers per minute on the polycrystalline structure.

Step E03 may be carried out in a reactor at a pressure of about 20 torr, with a gas mixture containing for example hydrochloric acid at a partial pressure of 2.5 torr.

Steps E02 and E03 are then repeated n times (step E04), the number n being chosen depending on the thickness desired for the multilayer epitaxially grown on the single-crystal structure.

It is in particular possible to change the composition of the epitaxially grown material in step E02, at least in some of these repetitions.

For example, it is possible to introduce dopants into the epitaxially grown semiconductor material and thus to control the doping profile through the superposition of epitaxially grown layers.

By way of example, when forming a silicon layer on the source and drain of a fully-depleted transistor, it is possible to obtain, after five repetitions of steps E02 and E03, a thickness of about twenty nanometers on the single-crystal structure without forming a protuberance on the polycrystalline structure.

For the repetitions of steps E02 and E03, various epitaxial and etching reactors may be used, and the temperatures and the pressures of the various gases may be changed so as to obtain the desired thicknesses.

It is also possible to use one and the same reactor for steps E02 and E03, and a constant temperature and a constant pressure.

Once the desired thickness of the epitaxially grown multilayer has been obtained, a final epitaxial growth step (E05) may be carried out.

This step makes it possible in particular to improve the surface finish of the last epitaxially grown layer, possibly damaged by the last etch step E03.

The final epitaxial growth step may be of short duration, for example half the duration of one of the epitaxial growth steps E02. Thus, the amount of material formed on the polycrystalline structure is negligible.

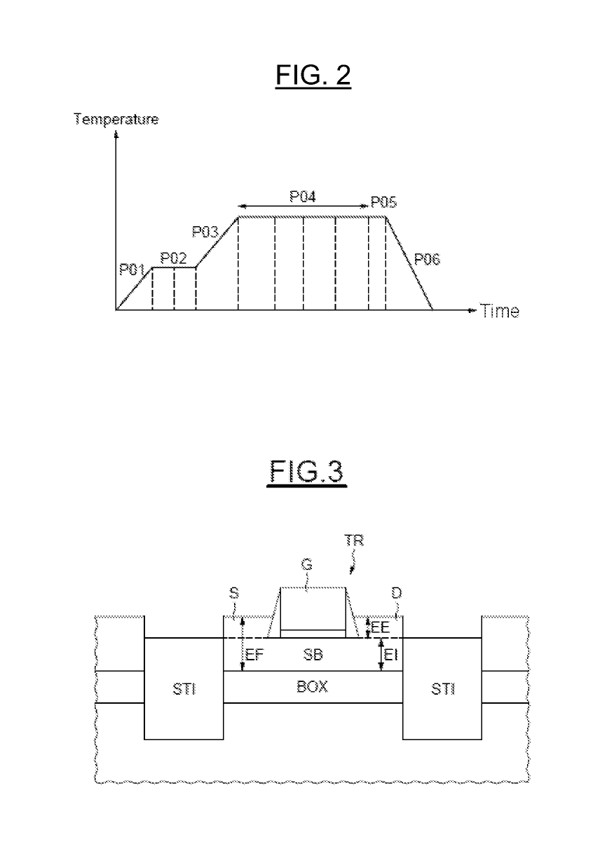

In FIG. 2, the variation in the temperature during a process according to one aspect of the invention has been shown graphically.

More precisely, the temperature variation has been shown for a process in which the epitaxial growth E02 and etching E03 steps are carried out in one and the same reactor and at a constant temperature and pressure.

In a first phase P01, the polycrystalline and single-crystal structures are subjected to a first temperature increase, so that the initial epitaxial growth and initial etching step E01 can be carried out (phase P02). A temperature of about 600° C. may be reached if silicon is to be formed.

Phase P02 comprises the initial epitaxial growth and initial etching steps, carried out for times shorter than a minute for example.

A second temperature ramp (phase P03) allows a sufficiently high temperature to be reached for the epitaxial growth steps E02 and the etching steps E03. A temperature of about 700° C. to 750° C. may for example be reached if silicon is to be formed.

The initial epitaxial growth and initial etching steps may also be carried out during phases P01, P02 and P03, i.e. in all the temperature ramp and temperature stabilization phases.

During phase P04, a loop E04 is implemented, comprising two epitaxial growth steps E02 and two etching steps E03.

The temperature and the pressure both remain constant during this phase P04.

Furthermore, for an epitaxial growth rate of five nanometers per minute on a single-crystal structure compared to ten nanometers per minute on a polycrystalline structure, and for an etch rate of one nanometer per minute for the single-crystal structure compared to 10 nanometers per minute for the polycrystalline structure, a final thickness of about 4 nanometers is obtained on the single-crystal structure and a zero thickness on the polycrystalline structure, after each cycle comprising one minute of deposition.

Phase P05 comprises the final epitaxial growth step E05, carried out at the same temperature as the steps in phase P04.

A phase P06 comprising a ramp down in temperature is finally implemented so as to allow the structures to be taken out of the reactor.

The invention is particularly well suited to producing fully-depleted transistors.

FIG. 3 shows a fully-depleted transistor TR obtained for example after the final epitaxial growth step E05.

It is particularly advantageous to use an initial epitaxial growth step for this type of transistor, for which the initial thicknesses EI of the single-crystal sources S and drains D, located in a substrate SB on an insulator BOX, are about two or three nanometers.

Thus, an epitaxially grown thickness EE forming a region of total thickness EF is obtained that allows contacts to be produced on these single-crystal structures.

Furthermore, an unchanged polycrystalline gate G (with no protuberance) is obtained without using a hard mask.

It will be noted that the epitaxial growth steps E02 and etching steps E03 also stop epitaxially grown semiconductor material from forming on a shallow trench isolation STI.

What is claimed is:

1. A process, comprising:
(a) growing a layer of a semiconductor material epitaxially on a single-crystal semiconductor structure and on a polycrystalline semiconductor structure;
(b) etching said epitaxial layer in order to preserve a non-zero thickness of said material on the single-crystal structure and a zero thickness on the polycrystalline structure; and
(c) repeating step (a) at least once, with the same material or with a different material, said single-crystal structure and said polycrystalline structure being obtained, respectively, from the preceding step (b), and repeating step (b) at least once, until the stack of epitaxial layers on said single-crystal structure has reached a desired thickness.

2. The process according to claim 1, further comprising, before step (a), epitaxially growing an initial semiconductor material on an initial single-crystal structure and an initial polycrystalline structure so as to obtain said single-crystal structure and said polycrystalline structure, said initial epitaxially growing step being carried out at a temperature below that of used in step (a) for growing the layer of a semiconductor material.

3. The process according to claim 2, further comprising, after epitaxially growing an initial semiconductor material, performing an initial etch in order to preserve a non-zero thickness of said material on the initial single-crystal structure and a zero thickness on the initial polycrystalline structure, said initial etch being carried out at a temperature below used in step (b) etching said epitaxial layer.

4. The process according to claim 1, further comprising, after step (c), growing a semiconductor material epitaxially on the single-crystal structure and polycrystalline structure.

5. The process according to claim 1, wherein steps (a) and (b) are carried out in one and the same epitaxial reactor at a constant temperature.

6. The process according to claim 1, wherein steps (a) and (b) are carried out in one and the same epitaxial reactor at a constant pressure.

7. The process according to claim 1, wherein, in step (a), the composition of the semiconductor material is different in at least two of the repetitions of this step.

8. The process according to claim 1, wherein the semiconductor material is chosen from the group consisting of silicon, germanium, a silicon-germanium alloy, a silicon-carbon alloy and a silicon-germanium-carbon alloy.

9. The process according to claim 1, wherein said single-crystal structure comprises source and drain regions of a transistor and said polycrystalline structure comprises a gate region of said transistor.

10. The process according to claim 9, wherein the transistor is a fully-depleted transistor.

11. A process, comprising:
forming a source region and drain region of single-crystal semiconductor material;
forming a gate structure of a polycrystalline semiconductor material;
performing a cyclic process including an epitaxial growth followed by an etch, wherein said epitaxial growth produces material on the source region, drain region and gate structure, and wherein the produced material is thicker on the gate structure than on the source and drain regions, and further wherein the etch is faster on the material formed on the gate structure than on the material formed on the source and drain regions so that the etch in each cycle completely removes the material from the gate structure while leaving material on the source and drain regions;
wherein the cyclic process is repeated until the material left on the source and drain regions achieves a certain thickness.

12. The process of claim 11, wherein said cyclic process is performed at a first temperature and first pressure.

13. The process of claim 12, further comprising, prior to performing the cyclic process, performing an initial epitaxial growth of material on the source region, drain region and gate structure.

14. The process of claim 13, wherein the initial epitaxial growth is performed at a second temperature and second pressure, and wherein the second temperature is lower than the first temperature.

15. The process of claim 13, further comprising, after performing the initial epitaxial growth and before performing the cyclic process, performing an etch to remove the initial epitaxial growth from the gate structure while leaving the initial material growth on the source and drain regions.

16. The process of claim 11, wherein the material produced by epitaxial growth in the cyclic process is different in at least two cycles of the cyclic process.

17. The process of claim 16, wherein the material is silicon-based in one cycle and silicon-germanium-based in another cycle.

18. The process of claim 16, wherein the material is silicon-based in one cycle and silicon-carbon-based in another cycle.

19. The process of claim 16, wherein the material is silicon-carbon-based in one cycle and silicon-germanium-based in another cycle.
